(19) United States
(12) Patent Application Publication
(10) Pub. No.: US 2020/0152810 A1
(43) Pub. Date: May 14, 2020

(54) CONDUCTIVE PASTE, ELECTRODE AND SOLAR CELL

(71) Applicant: JOHNSON MATTHEY PUBLIC LIMITED COMPANY, London (GB)

(72) Inventors: Jonathan Charles Shepley BOOTH, Berkshire (GB); Kirill ARAPOV, Maastricht (NL); Edwin Peter Kennedy CURRIE, Maastricht (NL); Beatriz CELA GREVEN, Maastricht (NL); Simon JOHNSON, Berkshire (GB); Roland KATZBACH, Maastricht (NL); Nicolas NOWAK, Amiens (FR)

(21) Appl. No.: 16/611,681

(22) PCT Filed: May 9, 2018
(86) PCT No.: PCT/GB2018/051249

§ 371 Date: Nov. 7, 2019

(30) Foreign Application Priority Data
May 12, 2017 (GB) 1707670.4

(51) Int. Cl. H01L 31/032; H01L 31/0224; H01L 31/18; H01B 1/16

(52) U.S. Cl. CPC H01L 31/0324; H01B 1/16; H01L 31/18; H01L 31/022425

(57) ABSTRACT

The present invention relates to a conductive paste for forming a conductive track or coating on a substrate, particularly suitable for use in solar cells. The paste comprises a solids portion dispersed in an organic medium, the solids portion comprising electrically conductive material and an inorganic particle mixture wherein the inorganic particle mixture comprises substantially crystalline particles. The present invention also relates to a method of preparing a conductive paste, a method for the manufacture of a surface electrode of a solar cell, an electrode for a solar cell and a solar cell.

### FIELD OF THE INVENTION

The present invention relates to conductive pastes which are particularly suitable for use in solar cells and methods for making those pastes, to a method of manufacturing a conductive track or coating on a surface e.g. of a solar cell, and to a surface of a solar cell having a conductive track or coating formed thereon.

### BACKGROUND OF THE INVENTION

Conductive (e.g. silver-containing) pastes are routinely used in the preparation of conductive tracks for solar cells, such as silicon solar cells. The pastes typically comprise conductive (e.g. silver) powder, glass frit, and sometimes one or more additional additives, all dispersed in an organic medium. In the manufacture of solar cells, typically such a paste is applied to a semi-conductor substrate (e.g. a wafer) via screen-printing and is subsequently fired (i.e. subjected to heat treatment). A glass frit is an amorphous mixture of metal oxides. The glass frit has several roles. During firing, it becomes a molten phase and so acts to bond the conductive track to the semiconductor wafer. However, the glass frit is also important in etching away the anti-reflective or passivation layer (usually silicon nitride) provided on the surface of the semiconductor wafer, to permit direct contact between the conductive track and the semiconductor. The glass frit is typically also important in forming an ohmic contact with the semiconductor emitter.

The quality of the contact between the conductive track and the semiconductor wafer is instrumental in determining the efficiency of the final solar cell. The best glass frits need to be optimised to flow at the correct temperature, and to provide the correct degree of etching of the antireflective layer. If too little etching is provided, then there will be insufficient contact between the semiconductor wafer and the conductive track, resulting in a high contact resistance. Conversely, excessive etching may lead to deposition of large islands of silver in the semiconductor, disrupting its p-n junction and thereby reducing its ability to convert solar energy into electrical energy.

Much recent attention has focussed on improving the glass frit materials included in conductive pastes for photovoltaic cells, to provide a good balance of properties.

Conductive pastes comprising conductive powder, glass frit, and sometimes one or more additional additives, all dispersed in an organic medium, are also used to form conductive tracks or conductive coatings in a range of other electronics applications, including passive electronic components, e.g. in terminal electrodes for zinc oxide varistor components, terminations for MLCC (multi-layer ceramic capacitors), electrodes on TCO (transparent conductive oxide) coated glass substrate, conductive layers on NTC (negative temperature coefficient) thermistors, metallization of functional piezoceramics; and automotive applications including antennae and heatable mirrors, windscreens and backlites.

### SUMMARY OF THE INVENTION

There remains a need for compositions suitable for use in conductive pastes for solar cells which provide an excellent (lowered) contact resistance without negatively influencing the p-n junction of a solar cell, and which flow at a suitable temperature for firing the conductive paste during manufacture of a solar cell.

The present inventors have found, surprisingly, that substantially crystalline particles included in a conductive paste may give results which are as good as or better than the results obtained for pastes including a glass. In particular, the present inventors have found that an inorganic particle mixture comprising substantially crystalline particles of metal compound is a suitable replacement for glass frit.

Accordingly, a first aspect the present invention provides a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z} and substantially crystalline particles of a compound of element D selected from binary oxides, carbonates, hydrogen carbonates, nitrates, acetates, oxalates, formates and organometallic compounds;
wherein:
A is a metal or mixture of two different metals;
B is a metal or metalloid different to A;
D is a metal or metalloid;
0<x≤2;
y is an integer; and
z is an integer;
wherein the solids portion is substantially lead-free.

In some embodiments of the first aspect, the compound of element D is a compound having the general formula DₘOₙ;
wherein:
D is a metal or metalloid;
m is an integer; and
n is an integer.

In a second aspect the invention provides a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z} and substantially crystalline particles of a compound of Te, Bi or Ce selected from binary oxides, carbonates, hydrogen carbonates, nitrates, acetates, oxalates, formates and organometallic compounds;
wherein:
A is a metal or mixture of two different metals;
B is a metal or metalloid different to A;
0≤x≤2;
y is an integer; and
z is an integer.

In some embodiments of the second aspect, the compound of Te, Bi or Ce is a compound with general formula DₘOₙ;
wherein:
D is selected from Te, Bi or Ce;
m is an integer; and
n is an integer.

In some embodiments of the second aspect the compound of Te, Bi or Ce is a binary oxide, for example selected from TeO₂, Bi₂O₃ and CeO₂.

In a third aspect the invention provides a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z}; wherein
A is a metal or mixture of two different metals;
B is a metal or metalloid different to A;
0≤x≤2;
y is an integer; and
z is an integer;
wherein the solids portion is substantially lead-free and substantially glass-free.

A fourth aspect of the invention is a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z};
wherein:
A is one or more alkali metals;
B is a metalloid;
0≤x≤2;
y is an integer; and
z is an integer.

In some embodiments of this aspect, B is selected from B (boron), Si, Ge, Sb, and Te. In some embodiments of this aspect, B is Te. In some embodiments of this aspect, x is 2 and y is 1. In some embodiments of this aspect, x is 2, y is 1 and z is 3.

A fifth aspect of the invention is a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z};
wherein:
A is one or more alkali metals;
B is a metal or metalloid different from A;
x is 2;
y is 3; and
z is an integer.

In some embodiments of this aspect, z is 7. In some embodiments of this aspect, A is selected from Li, Na or a mixture of Li and Na. In some embodiments of this aspect, B is selected from transition metals.

A sixth aspect of the invention is a conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z};
wherein:
A is one or more metals;
B is a metal or metalloid different from A;
x is less than 1;
y is an integer; and
z is an integer.

In some embodiments of this aspect, A is one or more alkali metals. In some embodiments of this aspect, A is Li. In some embodiments of this aspect, y is 1. In some embodiments of this aspect, z is 3.

A seventh aspect of the invention is a method of preparing a conductive paste according to any one of the first to sixth aspects, comprising mixing an organic medium and the components of a solids portion, in any order.

An eighth aspect of the invention is a method for the manufacture of a surface electrode of a solar cell, the method comprising applying a conductive paste as defined in any one of the first to sixth aspects to a semiconductor substrate, and firing the applied conductive paste.

A ninth aspect of the invention is an electrode for a solar cell, the electrode comprising a conductive track on a semiconductor substrate, wherein the conductive track is obtained or obtainable by firing a paste as defined in any one of the first to sixth aspects on the semiconductor substrate.

A tenth aspect of the invention is a solar cell comprising a surface electrode as defined in the ninth aspect.

An eleventh aspect of the invention is the use of a conductive paste as defined in any one of the first to sixth aspects in the manufacture of a surface electrode of a solar cell.

A twelfth aspect of the invention is the use of an additive having the general formula AₓB_{y}O_{z} in a conductive paste to improve the specific contact resistance of a solar cell, wherein:
A is a metal or mixture of two different metals;
B is a metal or metalloid different to A;
0≤x≤2;
y is an integer; and
z is an integer.

The conductive paste may, for example, be for use in the manufacture of a solar cell.

A particular advantage of using substantially crystalline particles of metal compound is that it removes the glass forming step from the process of manufacturing a conductive paste. The glass forming step typically has high energy demands, since it requires the glass precursors to be heated to temperatures above the melting point of crystalline materials used to manufacture the glass. Glasses are typically used in conductive pastes due to their relatively low softening and melting points. Typically, glasses used in conductive pastes flow at temperatures in the range of about 400-700° C. The present inventors have surprisingly found that despite the considerably higher melting point of at least some of the substantially crystalline metal compounds used in the pastes of the present invention, these mixtures still exhibit similar flow and melt behaviour to glass frits, which enables them to be used with a similar firing profile and manufacturing method as pastes comprising glass frit.

By “substantially crystalline” herein, we mean a crystalline material which has long-range structural order of atoms through the material. Such a material does not exhibit a glass transition. This contrasts with, for example, amorphous or glassy materials. Generally other differences will be that a substantially crystalline material will have a melting point rather than the softening point exhibited by amorphous materials, and a substantially crystalline material will give rise to multiple distinct peaks in an XRD pattern.

As the skilled person will understand, avoiding the energy intensive glass forming step has advantages outside the field of conductive pastes for solar cells. The present inventors consider that their invention is applicable also to conductive pastes used to form conductive tracks and conductive coatings in other electronics applications, such as those mentioned herein.

The present invention also relates to the inorganic blend (inorganic particle mixture) itself as described herein.

### BRIEF DESCRIPTION OF THE DRAWINGS

FIG. 1 shows an example firing curve for a solar cell prepared in the Examples.

FIG. 2 shows a powder X-ray diffractogram for the crystalline compound Li₂TeO₃.

### DETAILED DESCRIPTION

Preferred and/or optional features of the invention will now be set out. Any aspect of the invention may be combined with any other aspect of the invention unless the context demands otherwise. Any of the preferred and/or optional features of any aspect may be combined, either singly or in combination, with any aspect of the invention unless the context demands otherwise.

For example, the discussion of the inorganic particle mixture content, raw materials and particle size distribution is applicable to the aspects of the invention relating to pastes, methods and blends equally.

Conductive pastes of the present invention include an organic medium and a solids portion. The solids portion includes an electrically conductive metal and an inorganic particle mixture. Each of these will be discussed, as will various methods of utilising them to make a conductive paste.

### Solids Portion—Content

In some embodiments, the solids portion includes 0.1 to 15 wt % of inorganic particle mixture.

In some embodiments, the solids portion includes 80 to 99.9 wt % of electrically conductive material.

### Inorganic Particle Mixture—Content

The solids portion of the conductive pastes described herein contain an inorganic particle mixture.

In some embodiments, the inclusion of the inorganic particle mixture may reduce the contact resistance of the conductive paste.

The particulate nature of the inorganic particle mixture means that discrete, separate or individual particles of each inorganic component are present. The inorganic particle mixture comprises substantially crystalline particles. The substantially crystalline particles do not exhibit a glass transition.

In the solids portion, electrically conductive material and an inorganic particle mixture are present. It may be that these are the only components of the solids portion. The solids portion may therefore consist of only an electrically conductive material and an inorganic particle mixture.

In some embodiments of the present invention the content of amorphous oxide material, or glass, in the solids portion may be less than 1 wt %. It may be that the solids portion is substantially glass-free, for example, the glass content of the solids portion may be less than 1 wt %, less than 0.5 wt %, less than 0.25 wt %, less than 0.1 wt %, less than 0.05 wt % or less than 0.01 wt %, with respect to the total weight of the solids portion. In some embodiments the solids portion does not include any intentionally added glass and/or any intentionally formed glass phase.

In some embodiments of the present invention, the solids portion is substantially lead free, for example, the lead content of the solids portion may be less than 0.5 wt %, preferably less than 0.25 wt %, more preferably less than 0.05 wt %, most preferably less than 0.01 wt %. In some embodiments, the solids portion does not include any intentionally added lead.

It will be understood by the skilled reader that a glass material is not synonymous with an amorphous material, or even an amorphous region within a crystalline material. A glass material exhibits a glass transition. While glasses may include some crystalline domains (they may not be entirely amorphous) these are different from the discrete substantially crystalline particles described herein.

Of course, it will be recognised by the skilled person that some amorphous or glassy phase may be formed even when substantially crystalline raw materials are used due to the nature of the processing conditions used. In aspects of the present invention this is minimised. For example, there may be some surface reaction of the oxide particles induced by milling, or deposition of carbon from the breakdown of a raw material such as lithium carbonate.

However, the lack of glass transition (that is, a non-exhibition of glass transition) may characterise the difference from known materials.

Compound having the general formula AₓB_{y}O_{z}

Generally, the present inorganic particle mixture comprises substantially crystalline particles of a compound having the general formula AₓB_{y}O_{z}. In some embodiments they have a perovskite, spinel or bronze-type crystalline structure.

In the present application the formulae of the components of the inorganic particle mixture are not always best expressed using only integer values. They represent the ratio between the various elements A, B and O in the compound having the general formula AₓB_{y}O_{z}. In particular, the value of x is not necessarily an integer.

O represents the element oxygen.

‘A’ and ‘B’ can represent various different elements. The values of x, y and z can also vary. The skilled person will recognise that one choice of A, B, x, y or z may affect what is chosen for the remainder of A, B, x, y and z.

‘A’ is generally a metal or a mixture of two metals. In some embodiments, A is a metal which has an oxidation state of +1. For example, it may be an alkali metal, such as Li, Na or K or a mixture of alkali metals, for example a mixture of any two of Li, Na and K. In certain embodiments, A is Li or Na, or a mixture thereof.

In some embodiments, A is a metal with an oxidation state of +2 or a mixture of such metals. In some embodiments, A is an alkaline earth metal, such as Mg, Ca, Sr or Ba. In some embodiments, A is Mg. In some embodiments, A is a transition metal, such as Zn.

In some embodiments, A is not Ag.

‘B’ is generally a metal or metalloid. For example, it may be selected from transition metals, post-transition metals, lanthanides and metalloids. The transition metals are understood by the skilled person. Examples include Ti, Mo, Mn, W, Cr, Nb, V and Zn. The post-transition metals are also understood by the skilled person. Examples include Sn, Pb and Bi.

In some embodiments, B is selected from transition metals and metalloids.

The term ‘metalloid’ as used herein indicates an element selected from the group B (boron), Si, Ge, Sb and Te. The metalloid may be selected from Te, Si and Sb. In some embodiments, the metalloid is Te.

In some embodiments, ‘B’ is selected from transition metals. For example, B may be selected from Ti, Mo, Mn, W, Cr, Nb, V and Zn. In some embodiments B may be Ti, Mo, Mn, W, V or Cr. For example, it may be Ti, Mo, Mn or W.

In certain embodiments B is selected from Te, Ti and W.

In some embodiments, B is not Ru.

x is a value which indicates the level of inclusion of A in the crystalline structure. Generally, it is between 0 and 2. For example, x is greater than 0. It may be greater than or equal to 0.1, greater than or equal to 0.2, greater than or equal to 0.3, greater than or equal to 0.4, greater than or equal to 0.5, greater than or equal to 0.6, greater than or equal to 0.7, greater than or equal to 0.8, greater than or equal to 0.9, greater than or equal to 1, greater than or equal to 1.1, greater than or equal to 1.2, greater than or equal to 1.3, greater than or equal to 1.4, greater than or equal to 1.5, greater than or equal to 1.6, greater than or equal to 1.7, greater than or equal to 1.8, or greater than or equal to 1.9.

x is less than or equal to 2. It may be less than or equal to 1.9, less than or equal to 1.8, less than or equal to 1.7, less than or equal to 1.6, less than or equal to 1.5, less than or equal to 1.4, less than or equal to 1.3, less than or equal to 1.2, less than or equal to 1.1, less than or equal to 1, less than or equal to 0.9, less than or equal to 0.8, less than or equal to 0.7, less than or equal to 0.6, less than or equal to 0.5, less than or equal to 0.4, less than or equal to 0.3, less than or equal to 0.2, less than or equal to 0.1.

In some embodiments, x is 2. In some embodiments, x is 1. In some embodiments, x is less than 1.

y is an integer, and in some embodiments is an integer less than z. In some embodiments y is 1. In some embodiments y is 2. In some embodiments y is 3.

z is an integer. In some embodiments, z is an integer selected from within the range 1 to 10, for example 1 to 8, for example 2 to 7. In some embodiments z is 2. In some embodiments z is 3. In some embodiments z is 7.

In some embodiments, A is one or more metals with oxidation state less than or equal to 2; B is one or more metals or metalloids different from A; x is less than 1; y is 1 and z is an integer.

In some embodiments, A is one or more alkali metals; B is Te; x is 2; y is 1 and z is an integer.

In some embodiments, A is one or more alkali metals; B is a metal or metalloid different from A; x is 2; y is 3; and z is an integer.

Some particular compounds having the general formula AₓB_{y}O_{z} of use in the present invention will now be described.

The compound having the general formula AₓB_{y}O_{z} may have a general formula Aⁱ₂BⁱO₃, wherein Aⁱ and Bⁱ are as defined above for A and B respectively.

Aⁱ may be selected from Li, Na, K, Zn, Mg and mixtures thereof. In some embodiments, Aⁱ is Li. In some embodiments, Aⁱ is a mixture of Li and Na. In embodiments where Aⁱ is a mixture of Li and Na, the two elements may be present in any ratio. In some embodiments, the molar ratio of Li:Na within A is in the range 1:1 to to 8:1. In some embodiments, the molar ratio Li:Na within A is in the range 1:1 to 3:1, for example 2:1 to 3:1.

Bⁱ may be selected from Mo, Mn, W, Te and Bi. In some embodiments, Bⁱ is Te. In those embodiments the compound having the general formula AₓB_{y}O_{z} has the general formula Aⁱ₂TeO₃.

In some embodiments, Bⁱ is not Ru.

The compound having the general formula AₓB_{y}O, may be selected from Li₂TeO₃ and LiₐX_{b}TeO₃, for example, wherein X is an alkali metal different from Li (for example, Na) and the sum of a and b is 2.

The compound having the general formula AₓB_{y}O_{z} may have a general formula Aⁱ_{q}BⁱⁱO₃, wherein Aⁱⁱ and Bⁱⁱ are as defined above for A and B respectively and q is a value greater than 0 and less than or equal to 1.

Aⁱⁱ may be selected from Li, Na, K, Zn, Mg and mixtures thereof. For example, it may be Li or Na. In some embodiments, Aⁱⁱ is Na. In some embodiments, Aⁱⁱ is Li. In some embodiments, Aⁱⁱ is K.

Bⁱⁱ may be selected from Mo, Mn, W, Te and Bi. In some embodiments, Bⁱⁱ is W. In those embodiments the compound having the general formula AₓB_{y}O_{z} has the general formula Aⁱⁱ_{q}WO₃.

q is greater than 0. It may be greater than or equal to 0.1, greater than or equal to 0.2, greater than or equal to 0.3, greater than or equal to 0.4 or greater than or equal to 0.5.

q is less than or equal to 1. It may be less than or equal to 0.9, less than or equal to 0.8 or less than or equal to 0.7.

In some embodiments, q is from 0.2 to 0.9, for example 0.3 to 0.8, for example 0.4 to 0.7. In some embodiments q is about 0.6, that is, about 0.5 to about 0.7, or about 0.55 to about 0.65.

The compound having the general formula AₓB_{y}O_{z} may be Na_{0.6}WO₃, Li_{0.6}WO₃ or K_{0.6}WO₃, for example. In certain embodiments it is Li_{0.6}WO₃.

The compound having the general formula AₓB_{y}O_{z} may have a general formula AⁱⁱBⁱⁱⁱO₄, wherein Aⁱⁱⁱ and Bⁱⁱⁱ are as defined above for A and B.

Aⁱ may be selected from Li, Na, K and mixtures thereof. For example, it may be Li or Na. In some embodiments, Aⁱⁱⁱ is Na. In some embodiments, Aⁱⁱⁱ is Li. In some embodiments, Aⁱⁱⁱ is K.

Bⁱⁱⁱ may be selected from Mo, Mn, W, Te and Bi. In some embodiments, Bⁱⁱⁱ is Mn. In those embodiments, the compound having the general formula AₓB_{y}O_{z} has the general formula AⁱⁱⁱMnO₄.

The compound having the general formula AₓB_{y}O_{z} may be LiMnO₄, NaMnO₄ or KMnO₄, for example. In certain embodiments it is LiMnO₄.

The compound having the general formula AₓB_{y}O_{z} may have a general formula A^{iv}₂B^{iv}O₄, wherein A^{iv} and B^{iv} are as defined above for A and B respectively.

A^{iv} may be selected from Li, Na, K, Zn and Mg, or a mixture thereof. In some embodiments, A^{iv} is Li.

By may be selected from Mo, Mn, W, Te and Bi. In some embodiments, B^{iv} is Te. In those embodiments the compound having the general formula AₓB_{y}O_{z} has the general formula A^{iv}₂TeO₄.

The compound having the general formula A^{iv}₂B^{iv}O₄ may be Li₂TeO₄ or LiₐX_{b}TeO₄, wherein X is an alkali metal different from Li (for example, Na) and the sum of a and b is 2.

The compound having the general formula AₓB_{y}O_{z} may have a general formula A^{v}₂B^{v}₃O₇, wherein A^{v} and B^{v} are as defined above for A and B respectively.

A^{v} may be selected from Li, Na, K, Zn, Mg and mixtures thereof. For example, it may be Li or Na. In some embodiments, A^{v} is Na. In some embodiments, A^{v} is Li. In some embodiments, A^{v} is K.

By may be selected from Ti, Mo, Mn, W, Te and Bi. In some embodiments, B^{v} is Ti. In those embodiments the compound having the general formula AₓB_{y}O_{z} has the general formula A^{v}₂Ti₃O₇.

The compound having the general formula AₓB_{y}O_{z} may be Na₂Ti₃O₇.

The particle size of the compound having the general formula AₓB_{y}O_{z} is not particularly limited in the present invention. Typically, the D₅₀ particle size may be at least 0.25 μm, for example at least 0.3 μm, at least 0.4 μm, at least 0.5 μm, or at least 1 μm. The D₅₀ particle size may be 15 μm or less, 10 μm or less, 5 μm or less, 4 μm or less, 3 μm or less or 2 μm or less. The particle size may be determined using a laser diffraction method (e.g. using a Malvern Mastersizer 2000).

AₓB_{y}O_{z} includes two or more different metal/metalloid elements in a single crystalline phase. The skilled person understands that the presence of multiple types of metal/metalloid atom or ion in a crystalline phase or phases and possible secondary phases may be identified using XRD to confirm that the crystal structure of the substantially crystalline particles of the compound having the general formula AₓB_{y}O_{z} corresponds to the crystal structure of a compound (e.g. oxide) of multiple metal/metalloids. Other techniques which may be employed include TEM and SEM-EBSD. As the skilled person will also understand, a compound of multiple metal/metalloids may include incidental impurities which may be a different metal/metalloid atom or ion or may be a metal/metalloid the same as A or B but of different oxidation state. Such incidental impurities will be present in the metal/metalloid compound at a very low level (e.g. <1 mol %, or <0.5 mol % with respect to the entire metal/metalloid compound in question) and will not have a detrimental effect on the properties of the paste of the present invention.

### Compound of Element D

The compound of element D may be selected from binary oxides, carbonates, hydrogen carbonates, nitrates, acetates, oxalates, formates and organometallic compounds. As used herein, the term “binary oxides” refers to oxide compounds comprising oxygen and one other element only. Thus, a binary oxide of element D is a compound comprising atoms of oxygen and of element D only.

According to some aspects of the invention, the compound of element D is a compound having the general formula DₘOₙ. In the compound having the general formula DₘOₙ, D is a metal or metalloid, m is an integer, and n is an integer.

In some embodiments, D is a different metal or metalloid from each of A and B. In some embodiments, D is the same metal as A, or where A is a mixture of metals, D is the same as one of the metals of A. In some embodiments, D is the same metal or metalloid as B.

In some embodiments, D is selected from alkali metals, alkaline earth metals, transition metals, post-transition metals, metalloids and lanthanides. D may also be selected from some non-metals such as P in some embodiments.

In some embodiments, D is selected from alkali metals, for example Li, Na, K or Rb. In some embodiments, D is Li or Na.

In some embodiments, D is selected from alkaline earth metals, for example Mg, Ca, Sr or Ba.

In some embodiments, D is selected from transition metals, for example Zn or W.

In some embodiments, D is selected from post-transition metals, for example Bi.

In some embodiments, D is selected from metalloids, for example Te.

In some embodiments, D is selected from lanthanides, for example Ce.

In some embodiments, D is selected from Te, Ce, Bi, Si, Li, Na, K, Rb, Zn, Mo, Cr, W, Ba, Sr, Mg, P, Ge, Ca, Zr, Cu, Ag and Al. In some embodiments, D is selected from Te, Ce, Bi, Si, Li, Na, K, Rb, Zn, Mo, Cr, W, Ba and P. In some embodiments, D is selected from Bi, Te, W, Ce and Zn.

In some embodiments, D is selected from Te, Bi and Ce.

In some embodiments the compound having the general formula DₘOₙ includes substantially crystalline particles of a compound of tellurium, such as tellurium oxide, for example, paratellurite or TeO₂. In some embodiments the compound having the general formula DₘOₙ includes substantially crystalline particles of a compound of cerium, such as cerium oxide or CeO₂. In some embodiments the compound having the general formula DₘOₙ includes substantially crystalline particles of a compound of bismuth, e.g. bismuth oxide (Bi₂O₃).

In certain embodiments, ‘D’ includes substantially only one type of metal or metalloid element. That is, there may be substantially only a single cationic species present in the compound having the general formula DₘOₙ. For example, the presence of substantially only a single type of metal/metalloid atom or ion may be identified using XRD to confirm that the crystal structure of the substantially crystalline particles of the compound having the general formula DₘOₙ corresponds to the crystal structure of a compound (e.g. oxide) of a single metal or metalloid. As the skilled person will understand, a compound of a single metal or metalloid may include incidental impurities which may be a different metal/metalloid atom or ion. Such incidental impurities will be present in the metal/metalloid compound at a very low level (e.g. <1 mol %, or <0.5 mol % with respect to the entire metal/metalloid compound in question).

Furthermore, processing of the metal/metalloid compounds (e.g. co-milling) may induce some surface modification or reaction of the compounds. However, in this case the bulk of the material remains compound of a single metal/metalloid, and can still be identified by XRD as described above.

In some embodiments, m is an integer selected from 1 and 2. In some embodiments, n is an integer selected from 1, 2 and 3. In some embodiments, m and n are both 1. In some embodiments, one of m and n is 1 and the other is 2. In some embodiments, m is 1 and n is 2. In some embodiments, m is 1 and n is 3. In some embodiments, m is 2 and n is 3.

Some specific compounds represented by DₘOₙ which may be included in the present invention include TeO₂, Li₂O, Bi₂O₃, ZnO, MgO, Ce₂O₃, CeO₂, Na₂O, MoO₃ and WO₃.

In some aspects of the invention, the inorganic particle mixture further comprises, in addition to the compound having the general formula AₓB_{y}O_{z}, a compound of Te, Bi or Ce selected from binary oxides, carbonates, hydrogen carbonates, nitrates, acetates, oxalates, formates and organometallic compounds.

In some embodiments, the compound of Te, Bi or Ce is selected from binary oxides, carbonates, hydrogen carbonates, nitrates, acetates, oxalates and formates. In some embodiments, the compound of Te, Bi or Ce is selected from binary oxides, carbonates, and hydrogen carbonates. In some embodiments, the compound of Te, Bi or Ce is a binary oxide.

### Auxiliary Inorganic Materials

Generally, in addition to the particles of the compound having the general formula AₓB_{y}O_{z} (and, in some aspects, in addition to other components of the inorganic particle mixture discussed above), the inorganic particle mixture may further comprise one or more additional different particulate inorganic materials (hereafter denoted ‘auxiliary inorganic materials’) such as metal or metalloid compounds, e.g. oxides, carbonates, nitrates, hydrogen carbonates, oxalates, acetates or formates. The auxiliary inorganic materials may contain non-oxide materials and may be formed from materials which are not oxides. In some embodiments these auxiliary inorganic materials contain one or more compounds having the general formula DₘOₙ, as discussed above. Additionally or alternatively, these auxiliary inorganic materials contain one or more compounds having the general formula AₓB_{y}O_{z}, as discussed above.

Thus in some embodiments, the inorganic particle mixture comprises a compound having the general formula AₓB_{y}O_{z}, optionally one or more additional different compounds having the general formula AₓB_{y}O_{z}, and/or one or more compounds having the general formula DₘOₙ.

The particulate nature of the inorganic particle mixture means that discrete, separate or individual particles of each inorganic component are present. In some embodiments, the auxiliary inorganic materials may comprise or consist of substantially crystalline particles. The substantially crystalline particles do not exhibit a glass transition. The auxiliary inorganic materials may include a metal or metalloid oxide. It is apparent to the reader that many such oxides are known. The auxiliary inorganic materials may include substantially crystalline particles, which are typically substantially crystalline particles of a metal or metalloid compound. Each metal or metalloid compound of the auxiliary inorganic materials may, for example, be selected from an oxide, a carbonate or a nitrate. Particularly, compounds (e.g. oxides) of the sort generally used in the field of conductive paste manufacture for solar cells are contemplated.

Some specific metal or metalloid compounds which may be included in the auxiliary inorganic materials include one or more of TeO₂, Li₂O, Li₂CO₃, Bi₂O₃, Bi₅O(OH)₉(NO₃)₄, ZnO, MgO, Ce₂O₃, CeO₂, Na₂O, Na₂CO₃, H₂WO₄, MoO₂, WO₂, MoO₃ and WO₃.

For example, in some embodiments the auxiliary inorganic materials include substantially crystalline particles of a compound of tellurium, such as tellurium oxide, for example, paratellurite or TeO₂. In some embodiments the auxiliary inorganic materials include substantially crystalline particles of a compound of cerium, such as cerium oxide or CeO₂. In some embodiments the auxiliary inorganic materials include substantially crystalline particles of a compound of bismuth, e.g. bismuth nitrate, or bismuth oxide (Bi₂O₃).

The auxiliary inorganic materials may include two or more different metal or metalloid compounds, in some embodiments three or more, four or more, five or more or six or more different metal/metalloid compounds.

The content of the different compounds contained in the auxiliary inorganic materials may, of course, differ. There may be one, two, three or more compounds present in significantly higher amounts than the other compounds contained. For example, in some embodiments the content of the compound of tellurium (e.g. TeO₂) is higher than the content of any other metal/metalloid compound. In some embodiments, a compound of tellurium and a compound of bismuth are the two compounds present in the highest amounts that is, one of a compound of tellurium and a compound of bismuth is the compound present in the highest amount, and the other is the compound present in the second to highest amount. The amount as used herein may refer to the content by weight.

In certain embodiments, one or more (e.g. each) of the metal/metalloid compounds in the auxiliary inorganic materials includes substantially only one type of metal/metalloid element. That is, there may be substantially only a single cationic species present in a given compound included in the auxiliary inorganic materials. For example, the presence of substantially only a single type of metal/metalloid atom or ion may be identified using XRD to confirm that the crystal structure of the substantially crystalline particles of compound corresponds to the crystal structure of a compound (e.g. oxide) of a single metal or metalloid. As the skilled person will understand, a compound of a single metal or metalloid may include incidental impurities which may be a different atom or ion. Such incidental impurities will be present in the compound at a very low level (e.g. <1 mol %, or <0.5 mol % with respect to the entire compound in question). Furthermore, processing of the compounds (e.g. co-milling) may induce some surface modification or reaction of the compounds. However, in this case the bulk of the material remains compound of a single metal/metalloid, and can still be identified by XRD as described above.

Two or more of the metal/metalloid compounds, in some embodiments three or more, four or more, five or more or six or more of the compounds in the auxiliary inorganic materials includes substantially only one type of metal/metalloid element.

Accordingly, in some embodiments each compound or other material included in the auxiliary inorganic materials includes only one type of metal or metalloid element. It may therefore be that the auxiliary inorganic materials are substantially free of mixed metal/metalloid compounds, e.g. mixed oxides. Mixed oxides include more than one type of metal/metalloid element. Mixed oxides may be substantially crystalline or substantially amorphous. In particular, amorphous mixed oxides may be glass frits.

As used herein, the term “substantially free of mixed oxides” is intended to include auxiliary inorganic materials which contain no intentionally added mixed oxides. For example, the auxiliary inorganic materials may include less than 0.1 wt % mixed oxide, for example less than 0.05 wt %, less than 0.01 wt % or less than 0.005 wt % mixed oxide. For example, the auxiliary inorganic materials may include no intentionally added mixed oxide. As used herein, the term “substantially free of mixed metal compounds” should be interpreted analogously. For example, the auxiliary inorganic materials may be substantially glass-free.

Except where specified otherwise, the inorganic compound contents described herein are given as weight percentages. These weight percentages are with respect to the total weight of the inorganic particle mixture. The weight percentages are the percentages of the components used as starting materials in preparation of the inorganic particle mixture or conductive paste, on an oxide basis unless specified otherwise.

The auxiliary inorganic materials described herein are not generally limited. Many different oxides which are suitable for use in conductive pastes for solar cells are well known in the art.

It may be preferable that the auxiliary inorganic materials are substantially lead-free, for example, the auxiliary inorganic materials may include less than 0.1 wt % PbO, for example less than 0.05 wt %, less than 0.01 wt % or less than 0.005 wt % PbO.

Lead-free materials provide a final product of lower toxicity.

It may be preferable that the auxiliary inorganic materials are substantially boron-free. As used herein, the term “substantially boron-free” is intended to include auxiliary inorganic materials which contain no intentionally added boron. For example, the auxiliary inorganic materials may include less than 0.1 wt % boron (calculated as B₂O₃), for example less than 0.05 wt %, less than 0.01 wt % or less than 0.005 wt % (calculated as B₂O₃).

In some embodiments, the auxiliary inorganic materials include a compound of tellurium, e.g. TeO₂. The inorganic particle mixture may include at least 20 wt %, at least 25 wt %, or at least 30 wt % of the compound of tellurium (calculated as TeO₂). The inorganic particle mixture may include 80 wt % or less, 75 wt % or less, 70 wt % or less, 65 wt % or less or 60 wt % or less of the compound of tellurium (calculated as TeO₂). For example, the inorganic particle mixture may include 30 to 65 wt % of the compound of tellurium (calculated as TeO₂).

In some embodiments, the auxiliary inorganic materials include a compound of bismuth, e.g. Bi₂O₃. The inorganic particle mixture may include at least 10 wt %, at least 15 wt %, at least 18 wt %, at least 20 wt % or at least 25 wt % of the compound of bismuth (calculated as Bi₂O₃). The inorganic particle mixture may include 60 wt % or less, 55 wt % or less, 50 wt % or less or 45 wt % or less of the compound of bismuth (calculated as Bi₂O₃). For example, the inorganic particle mixture may include 20 to 50 wt % of the compound of bismuth (calculated as Bi₂O₃).

Alternatively, the compound of bismuth may be a bismuth nitrate, e.g. Bi₅O(OH)₉(NO₃)₄. The nitrate of bismuth (e.g. Bi₅O(OH)₉(NO₃)₄) may be used in the inorganic particle mixture in an amount of at least 10 wt %, at least 15 wt %, at least 18 wt %, at least 20 wt % or at least 25 wt %. It may be used in an amount of 60 wt % or less, 55 wt % or less, 50 wt % or less or 45 wt % or less. For example, it may be used in an amount of 20 to 50 wt %. In some embodiments, it may be preferable that Bi₂O₃ is used.

In some embodiments, the auxiliary inorganic materials include a compound of cerium (e.g. CeO₂). The inorganic particle mixture may comprise 0 wt % or more, e.g. at least 0 0.1 wt %, at least 0.2 wt %, at least 0.5 wt %, at least 1 wt %, at least 1.5 wt %, at least 2 wt %, at least 2.5 wt %, or at least 3 wt % of the compound of cerium (calculated as CeO₂). The inorganic particle mixture may comprise 22 wt % or less, 20 wt % or less, 17 wt % or less, 15 wt % or less, 14 wt % or less, 13 wt % or less, 12 wt % or less, 11 wt % or less, 10 wt % or less, or 8 wt % or less of the compound of cerium (calculated as CeO₂). A particularly suitable CeO₂ content is from 1 wt % to 15 wt %.

The auxiliary inorganic materials may include a compound of silicon (e.g. SiO₂). For example, the inorganic particle mixture may include 0 wt % or more, 0.1 wt % or more, 0.5 wt % or more or 1 wt % or more, 2 wt % or more or 2.5 wt % or more of the compound of silicon (calculated as SiO₂). The inorganic particle mixture may include 20 wt % or less, 15 wt % or less, 10 wt % or less, 7 wt % or less or 5 wt % or less of the compound of silicon (calculated as SiO₂). For example, the inorganic particle mixture may include 0.1 to 7 wt % of SiO₂.

In some embodiments, it may be preferred that the auxiliary inorganic materials are substantially silicon-free. As used herein, the term “substantially silicon-free” is intended to include auxiliary inorganic materials which contain no intentionally added silicon. For example, the auxiliary inorganic materials may include less than 0.1 wt % silicon (calculated as SiO₂), for example less than 0.05 wt %, less than 0.01 wt % or less than 0.005 wt % silicon (calculated as SiO₂).

The auxiliary inorganic materials may include alkali metal compound, for example one or more selected from compounds of lithium, sodium, potassium and rubidium, preferably one or more selected from compounds of lithium, sodium and potassium, more preferably one or both of compounds of lithium and sodium. One or more (e.g. each) alkali metal compound may conveniently be an alkali metal carbonate. In some embodiments, it is preferred that the auxiliary inorganic materials include a compound of lithium, e.g. lithium carbonate.

The auxiliary inorganic materials may include 0 wt % or more, 0.1 wt % or more, 0.5 wt % or more or 1 wt % or more alkali metal compound, calculated on an oxide basis. The auxiliary inorganic materials may include 20 wt % or less, 19 wt % or less, 18 wt % or less, 15 wt % or less, 12 wt % or less alkali metal compound, calculated on an oxide basis.

It is noted that one particular raw material which can be used to prepare auxiliary inorganic materials and conductive pastes which include a compound of lithium is Li₂CO₃. It may be used as a raw material in an amount of 0 wt % or more, 1 wt % or more, 2 wt % or more, 4 wt % or more, 5 wt % or more or 6 wt % or more of the inorganic particle mixture. It may be used as a raw material in an amount of 20 wt % or less, 15 wt % or less, 13 wt % or less, 6 wt % or less 10 wt % or less, or 8 wt % or less of the inorganic particle mixture. For example, it may be used as a raw material in an amount of 5 to 12.5 wt % of the inorganic particle mixture.

It is noted that one particular raw material which can be used to prepare auxiliary inorganic materials and conductive pastes which include a compound of sodium is Na₂CO₃. It may be used as a raw material in an amount of 0 wt % or more, 0.05 wt % or more, 0.1 wt % or more, 1 wt % or more, 2 wt % or more or 3 wt % or more of the inorganic particle mixture. It may be used as a raw material in an amount of 20 wt % or less, 15 wt % or less, 13 wt % or less, 6 wt % or less 10 wt % or less, 8 wt % or less, 7 wt % or less, 6 wt % or less or 5 wt % or less of the inorganic particle mixture. For example, it may be used as a raw material in an amount of 0.05 to 4 wt % of the inorganic particle mixture.

In some embodiments, the auxiliary inorganic materials include both a compound of tellurium and a compound of lithium. For example, both tellurium oxide and lithium oxide may be contained. The ratio of these compounds of lithium and tellurium may also be controlled in aspects of the present invention. For example, the molar ratio of Te to Li (Te:Li ratio) in the inorganic particle mixture may be in the range from 1:1 to 100:1. The Te:Li ratio may be at least 2:1, at least 3:1, at least 4:1, at least 5:1 or at least 6:1. The Te:Li ratio may be 100:1 or less, 50:1 or less, 25:1 or less, 20:1 or less, 15:1 or less, 10:1 or less, 8:1 or less, 7.5:1 or less, or 7:1 or less. For example, the molar ratio of Te to Li (Te:Li ratio) in the inorganic particle mixture may be in the range from 3:1 to 10:1, e.g. in the range from 5:1 to 8:1.

The auxiliary inorganic materials may include a compound of zinc (e.g. ZnO). For example, the inorganic particle mixture may include 0 wt % or more, 0.1 wt % or more, 0.5 wt % or more, 1 wt % or more or 1.2 wt % or more of the compound of zinc, (calculated as ZnO). The inorganic particle mixture may include 15 wt % or less, 10 wt % or less, 7 wt % or less or 5 wt % or less of the compound of zinc (calculated as ZnO). For example, the inorganic particle mixture may include 0.5 to 7 wt % of a compound of zinc, calculated as ZnO.

In some embodiments, it may be preferred that the auxiliary inorganic materials are substantially zinc-free. As used herein, the term “substantially zinc-free” is intended to include auxiliary inorganic materials which contain no intentionally added zinc. For example, the auxiliary inorganic materials may include less than 0.1 wt % zinc (calculated as ZnO), for example less than 0.05 wt %, less than 0.01 wt % or less than 0.005 wt % zinc (calculated as ZnO).

The auxiliary inorganic materials may include a compound of molybdenum (e.g. MoO₃). For example, the inorganic particle mixture may include 0 wt % or more, 0.1 wt % or more, 0.5 wt % or more of the compound of molybdenum (calculated as MoO₃). The inorganic particle mixture may include 10 wt % or less, 5 wt % or less, or 3 wt % or less of the compound of molybdenum (calculated as MoO₃). For example, the inorganic particle mixture may include 0.1 to 5 wt % of molybdenum (calculated as MoO₃).

In some embodiments, it may be preferred that the auxiliary inorganic materials are substantially molybdenum-free. As used herein, the term “substantially molybdenum-free” is intended to include auxiliary inorganic materials which contain no intentionally added molybdenum. For example, auxiliary inorganic materials may include less than 0.1 wt % molybdenum (calculated as MoO₃), for example less than 0.05 wt %, less than 0.01 wt % or less than 0.005 wt % molybdenum (calculated as MoO₃).

The auxiliary inorganic materials may include a compound of chromium (e.g. Cr₂O₃). For example, the inorganic particle mixture may include 0 wt % or more, 0.1 wt % or more, 0.5 wt % or more of the compound of chromium (calculated as Cr₂O₃). The inorganic particle mixture may include 10 wt % or less, 5 wt % or less, or 3 wt % or less of chromium (calculated as Cr₂O₃). For example, the inorganic particle mixture may include 0.1 to 5 wt % of chromium (calculated as Cr₂O₃).

In some embodiments, it may be preferred that the auxiliary inorganic materials are substantially chromium-free. As used herein, the term “substantially chromium-free” is intended to include auxiliary inorganic materials which contain no intentionally added chromium. For example, the auxiliary inorganic materials may include less than 0.1 wt % chromium (calculated as Cr₂O₃), for example less than 0.05 wt %, less than 0.01 wt % or less than 0.005 wt % chromium (calculated as Cr₂O₃).

The auxiliary inorganic materials may include a compound of tungsten (e.g. WO₃). For example, the inorganic particle mixture may include 0 wt % or more, 0.1 wt % or more, 0.5 wt % or more of the compound of tungsten (calculated as WO₃). The inorganic particle mixture may include 15 wt % or less, 10 wt % or less, or 5 wt % or less of the compound of tungsten (calculated as WO₃). For example, the inorganic particle mixture may include 0.1 to 5 wt % of the compound of tungsten (calculated as WO₃).

In some embodiments, it may be preferred that the auxiliary inorganic materials are substantially tungsten-free. As used herein, the term “substantially tungsten-free” is intended to include auxiliary inorganic materials which contain no intentionally added tungsten. For example, the auxiliary inorganic materials may include less than 0.1 wt % tungsten (calculated as WO₃), for example less than 0.05 wt %, less than 0.01 wt % or less than 0.005 wt % tungsten (calculated as WO₃).

The auxiliary inorganic materials may include a compound of barium (e.g. BaO or BaCO₃). For example, the inorganic particle mixture may include 0 wt % or more, 0.1 wt % or more, 0.5 wt % or more of the compound of barium (calculated as BaO or BaCO₃ respectively). The inorganic particle mixture may include 10 wt % or less, 5 wt % or less, or 3 wt % or less of the compound of barium (calculated as BaO or BaCO₃ respectively). For example, the inorganic particle mixture may include 0.1 to 5 wt % of the compound of barium (calculated as BaO or BaCO₃ respectively).

The auxiliary inorganic materials may include a compound of phosphorus (e.g. P₂O₅). For example, the inorganic particle mixture may include 0 wt % or more, 0.1 wt % or more, 0.5 wt % or more or 1 wt % or more of the compound of phosphorus (calculated as P₂O₅). The inorganic particle mixture may include 10 wt % or less, 7 wt % or less, 5 wt % or less or 3 wt % or less of the compound of phosphorus (calculated as P₂O₅).

The auxiliary inorganic materials may include further components, such as further oxide components. Typically, the auxiliary inorganic materials will include 20 wt % or less, 10 wt % or less, 7 wt % or less, 5 wt % or less, 3 wt % or less, 2 wt % or less or 1 wt % or less in total of further components. The auxiliary inorganic materials may include at least 0.1 wt % of further components. The further components may be one or more selected from the group consisting of compounds of germanium, calcium, zirconium, copper, silver and aluminium, e.g. GeO₂, CaO, ZrO₂, CuO, Ag₂O and Al₂O₃.

Selection of the ingredients of the inorganic particle mixture may be guided by the desired flow behaviour on firing. The inventors have found certain mixtures particularly suitable. For example, the inorganic particle mixture may preferably contain a mixture of ingredients providing a source of tellurium (for example, TeO₂) and a source of alkali metal, preferably lithium (for example, Li₂CO₃ or Li₂O). A source of bismuth (for example, Bi₂O₃ or Bi₅O(OH)₉(NO₃)₄) may also be included. A source of zinc (for example, ZnO) may also be included. The contents may be as described as above.

In some embodiments, the inorganic particle mixture comprises substantially crystalline particles of a compound having the general formula AₓB_{y}O_{z} as described above, along with auxiliary inorganic materials, wherein the auxiliary inorganic materials provide a source of at least one metal or metalloid which is different to both A and B. So, for example, where A is lithium and B is tellurium, in these embodiments the auxiliary inorganic materials include at least a metal or metalloid compound which provides a source of a metal/metalloid which is not Li or Te (so may be, for example, Bi and/or Ce and/or Zn and/or Ba).

In some embodiments, the inorganic particle mixture comprises substantially crystalline particles of a compound having the general formula AₓB_{y}O_{z} as described above, along with auxiliary inorganic materials, wherein the auxiliary inorganic materials provide a source of two, three, four or five different metals/metalloids, each of which are different from both A and B.

In some embodiments, the inorganic particle mixture comprises substantially crystalline particles of a compound having the general formula AₓB_{y}O_{z} as described above, along with auxiliary inorganic materials, wherein the auxiliary inorganic materials consist of at least one metal/metalloid oxide and/or carbonate compound each containing a single metal/metalloid, and wherein the auxiliary inorganic materials provide a source of at least one metal or metalloid which is different to both A and B.

The inventors have found that, when the inorganic particle mixture comprises AₓB_{y}O_{z} as a source of A and B, the contact resistance of the resultant silver contacts is lower (i.e. better) than for a corresponding inorganic particle mixture containing the same molar amounts of all metals/metalloids but where A and B are provided only by separate compounds of A and B respectively.

The inorganic particle mixture may consist essentially of a composition as described herein, and incidental impurities. In that case, as the skilled person will readily understand that the total weight % of the recited constituents will be 100 wt %, any balance being incidental impurities. For example, in one embodiment the inorganic particle mixture may consist of substantially crystalline particles of the compound having the general formula AₓB_{y}O_{z} as described above, auxiliary inorganic materials as described above and incidental impurities. In another embodiment, the inorganic particle mixture may consist of substantially crystalline particles of the compound having the general formula AₓB_{y}O_{z} as described above, substantially crystalline particles of a compound having the general formula DₘOₙ as described above, auxiliary inorganic materials as described above and incidental impurities. Typically, any incidental impurity will be present at 0.1 wt % or less, 0.05 wt % or less, 0.01 wt % or less, 0.05 wt % or less, 0.001 wt % or less or 0.0001 wt % or less.

The solids portion of the conductive paste of the present invention may include 0.1 to 15 wt % of the inorganic particle mixture. The solids portion of the conductive paste may include at least 0.5 wt % or at least 1 wt % of the inorganic particle mixture. The solids portion of the conductive paste may include 10 wt % or less, 7 wt % or less or 5 wt % or less of the inorganic particle mixture.

It may be preferred that the inorganic particle mixture comprises at least compounds of lithium and tellurium. It may be preferred that the inorganic particle mixture comprises at least compounds of lithium, tellurium and bismuth. It may be preferred that the inorganic particle mixture comprises at least compounds of lithium, tellurium and zinc.

It may be preferred that the inorganic particle mixture comprises at least compounds of lithium, tellurium, zinc and bismuth. It may be preferred that the inorganic particle mixture comprises at least compounds of lithium, tellurium, sodium, bismuth and zinc. It may be preferred that the inorganic particle mixture comprises at least compounds of lithium, tellurium and cerium. It may be preferred that the inorganic particle mixture comprises at least compounds of lithium, tellurium, cerium and bismuth. It may be preferred that the inorganic particle mixture comprises at least compounds of lithium, tellurium, cerium and zinc. It may be preferred that the inorganic particle mixture comprises at least compounds of lithium, tellurium, zinc, cerium and bismuth. It may be preferred that the inorganic particle mixture comprises at least compounds of lithium, tellurium, sodium, bismuth, cerium and zinc.

### Inorganic Particle Mixture Particle Size

In some embodiments, the inorganic particle mixture has a particle size distribution in which either
(a) D₁₀≤0.41 μm;
(b) D₅₀≤1.6 μm;
(c) D₉₀≤4.1 μm;
(d) (D₅₀−D₁₀)≤1.15 μm;
(e) (D₉₀−D₅₀)≤2.5 μm;
(f) (D₉₀−D₁₀)≤3.7 μm; or
(g) (D₅₀/D₁₀)≤3.85.

One or more, two or more, three or more, four or more, five or more or six or more of these requirements may be met in the present invention.

In some embodiments, requirement (a) is met. In some embodiments requirement (b) is met. In some embodiments, requirement (c) is met. In some embodiments, requirement (d) is met. In some embodiments, requirement (e) is met. In some embodiments, requirement (f) is met. In some embodiments, requirement (g) is met.

Any combination of these requirements may be met in some embodiments of the invention.

Regarding requirement (a), D₁₀ is 0.41 μm or lower, for example 0.4 μm or lower, 0.39 μm or lower, 0.35 μm or lower, 0.32 μm or lower, 0.3 μm or lower, 0.28 μm or lower, 0.25 μm or lower or 0.24 μm or lower.

The value of D₁₀ is preferably 0.4 μm or lower.

Typically, the D₁₀ particle size may be at least 0.1 μm, at least 0.12 μm, at least 0.14 μm, at least 0.17 μm or at least 0.2 μm.

Accordingly, in some embodiments D₁₀ is within the range 0.2 μm≤D₁₀≤0.4 μm.

Regarding requirement (b), the D₅₀ of the inorganic particle mixture is preferably less than or equal to 1.6 μm. The D₅₀ may be 1.55 μm or lower, 1.5 μm or lower, 1.45 μm or lower, 1.4 μm or lower, 1.35 μm or lower, 1.3 μm or lower, 1.25 μm or lower, 1.2 μm or lower, 1.15 μm or lower, 1.1 μm or lower, 1.05 μm or lower, 1 μm or lower or 0.95 μm or lower.

The value of D₅₀ is preferably 1.05 μm or lower.

Typically, the D₅₀ particle size may be at least 0.1 μm, at least 0.3 μm, at least 0.5 μm, or at least 0.8 μm.

Accordingly, in some embodiments D₅₀ is within the range 0.3 μm≤D₅₀≤1.05 μm.

Regarding requirement (c), the D₉₀ of the inorganic particle mixture is preferably less than or equal to 4.1 μm. The D₉₀ may be 4 μm or lower, 3.8 μm or lower, 3.6 μm or lower, 3.4 μm or lower, 3.2 μm or lower, 3 μm or lower, 2.8 μm or lower, 2.6 μm or lower, 2.4 μm or lower, 2.2 μm or lower, 2.1 μm or lower, 2 μm or lower or 1.9 μm or lower.

The value of D₉₀ is preferably 2.2 μm or lower.

Typically, the D₉₀ particle size may be at least 1 μm, at least 1.2 μm, at least 1.4 μm, or at least 1.5 μm.

Accordingly, in some embodiments D₉₀ is within the range 1.4 μm≤D₉₀≤2.2 μm.

Regarding requirement (d), (D₅₀−D₁₀) is 1.15 μm or lower, for example 1.1 μm or lower, 1 μm or lower, 0.8 μm or lower, 0.6 μm or lower, 0.59 μm or lower, 0.58 μm or lower, 0.57 μm or lower, 0.56 μm or lower, 0.55 μm or lower, 0.54 μm or lower or 0.53 μm or lower.

The value of (D₅₀−D₁₀) is preferably 0.6 μm or lower.

Typically, the difference between D₅₀ and D₁₀ may be at least 0.1 μm, at least 0.2 μm, at least 0.3 μm, or at least 0.35 μm.

Accordingly, in some embodiments (D₅₀−D₁₀) is within the range 0.3 μm≤(D₅₀−D₁₀)≤0.6 μm.

Regarding requirement (e), (D₉₀−D₅₀) is 2.5 μm or lower, for example 2 μm or lower, 1.75 μm or lower, 1.5 μm or lower, 1.25 μm or lower, 1.15 μm or lower, 1.1 μm or lower, 1.05 μm or lower, 1 μm or lower or 0.95 μm or lower.

The value of (D₉₀−D₅₀) is preferably 1.15 μm or lower.

Typically, the difference between D₉₀ and D₅₀ may be at least 0.5 μm, at least 0.6 μm, at least 0.7 μm, or at least 0.75 μm.

Accordingly, in some embodiments (D₉₀−D₅₀) is within the range 0.6 μm≤(D₉₀−D₅₀) 1.15 μm.

Regarding requirement (f), (D₉₀−D₁₀), that is, the difference between D₉₀ and D₁₀, is preferably less than or equal to 3.7 μm. The value of (D₉₀−D₁₀) may be 3.5 μm or lower, 3 μm or lower, 2.5 μm or lower, 2 μm or lower, 1.8 μm or lower, 1.6 μm or lower, 1.5 μm or lower, 1.45 μm or lower, 1.4 μm or lower, or 1.35 μm or lower.

The value of (D₉₀−D₁₀) is preferably 1.8 μm or lower.

Typically, (D₉₀−D₁₀) may be at least 1 μm, at least 1.1 μm, at least 1.2 μm, or at least 1.3 μm.

Accordingly, in some embodiments (D₉₀−D₁₀) is within the range 1.1 μm≤(D₉₀−D₁₀)≤1.8 μm.

Regarding requirement (g), (D₅₀/D₁₀), that is, the value obtaining by dividing D₅₀ by D₁₀, is less than or equal to 3.85. The value of (D₅₀/D₁₀) may be 3.8 or lower, 3.7 or lower, 3.6 or lower, 3.5 or lower, 3.4 or lower, 3.3 or lower, 3.2 or lower, 3.1 or lower, 3 or lower, 2.8 or lower, or 2.6 or lower.

The value of (D₅₀/D₁₀) is preferably 3.6 or lower.

Typically, (D₅₀/D₁₀) may be at least 1, at least 1.5, at least 2, or at least 2.3 μm.

Accordingly, in some embodiments (D₅₀/D₁₀) is within the range 2.2≤(D₅₀/D₁₀)≤3.6.

The particle sizes and distributions described herein may be determined using a laser diffraction method (e.g. using a Malvern Mastersizer 2000).

### Glass Frit

Whilst in some embodiments of the present invention it is preferred that the solids portion is substantially glass-free, in other embodiments, as explained above, in addition to the electrically conductive material and the inorganic particle mixture, the solids portion of the invention may further include particles of glass frit.

The glass frit compositions described herein are given in terms of weight percentages. These weight percentages are with respect to the total weight of the glass frit. The weight percentages are the percentages of the components used as starting materials in preparation of the glass frit compositions, on an oxide basis. As the skilled person will understand, starting materials such as oxides, carbonates or nitrates may be used in preparing the glasses of the present invention. Where a non-oxide starting material is used to supply a particular element to the glass frit, an appropriate amount of starting material is used to supply an equivalent molar quantity of the element had the oxide of that element been supplied at the recited wt %. This approach to defining glass compositions is typical in the art. As the skilled person will readily understand, volatile species (such as oxygen) may be lost during the manufacturing process of the glass frit, and so the composition of the resulting glass frit may not correspond exactly to the weight percentages of starting materials, which are given herein on an oxide basis. Analysis of a fired glass frit by a process known to those skilled in the art, such as Inductively Coupled Plasma Emission Spectroscopy (ICP-ES), can be used to calculate the starting components of the glass frit composition in question.

The glass frit described herein is not generally limited. Many different glass frit compositions which are suitable for use in conductive pastes for solar cells are well known in the art.

It may be preferable that the glass frit is substantially lead-free, for example, the glass frit may include less than 0.1 wt % PbO, for example less than 0.05 wt %, less than 0.01 wt % or less than 0.005 wt % PbO.

It may be preferable that the glass frit is substantially boron-free. As used herein, the term “substantially boron-free” is intended to include glass compositions which contain no intentionally added boron. For example, the glass frit may include less than 0.1 wt % B₂O₃, for example less than 0.05 wt %, less than 0.01 wt % or less than 0.005 wt % B₂O₃.

In some embodiments, the glass frit includes TeO₂. The glass frit may include at least 20 wt %, at least 25 wt %, at least 30 wt %, at least 35 wt %, at least 40 wt %, or at least 45 wt % of TeO₂. The glass frit may include 70 wt % or less, 65 wt % or less or 60 wt % or less of TeO₂. For example, the glass frit may include 35 to 65 wt % of TeO₂.

In some embodiments, the glass frit includes Bi₂O₃. The glass frit may include at least 10 wt %, at least 15 wt %, at least 18 wt %, at least 20 wt % or at least 25 wt % of Bi₂O₃. The glass frit may include 60 wt % or less, 55 wt % or less, 50 wt % or less or 45 wt % or less of Bi₂O₃. For example, the glass frit may include 20 to 50 wt % of Bi₂O₃.

In certain embodiments, the glass frit may be a tellurium-bismuth glass frit.

In some embodiments, the glass frit includes CeO₂. The glass frit may comprise 0 wt % or more, e.g. at least 0 0.1 wt %, at least 0.2 wt %, at least 0.5 wt %, at least 1 wt %, at least 1.5 wt %, at least 2 wt %, at least 2.5 wt %, at least 3 wt % CeO₂, at least 3.5 wt % CeO₂, at least 4 wt % CeO₂, at least 4.5 wt % CeO₂, at least 5 wt % CeO₂, at least 6 wt % CeO₂, or at least 7 wt % CeO₂. The glass frit may comprise 22 wt % or less, 20 wt % or less, 17 wt % or less, 15 wt % or less, 14 wt % or less, 13 wt % or less, 12 wt % or less, 11 wt % or less, 10 wt % or less, or 5 wt % or less of CeO₂. A particularly suitable CeO₂ content is from 1 wt % to 15 wt %.

The glass frit may include SiO₂. For example, the glass frit may include 0 wt % or more, 0.1 wt % or more, 0.5 wt % or more or 1 wt % or more, 2 wt % or more or 2.5 wt % or more SiO₂. The glass frit may include 20 wt % or less, 15 wt % or less, 10 wt % or less, 7 wt % or less or 5 wt % or less SiO₂. For example, the glass frit may include 0.1 to 7 wt % of SiO₂.

In some embodiments, it may be preferred that the glass frit is substantially silicon-free. As used herein, the term “substantially silicon-free” is intended to include glass compositions which contain no intentionally added silicon. For example, the glass frit may include less than 0.1 wt % SiO₂, for example less than 0.05 wt %, less than 0.01 wt % or less than 0.005 wt % SiO₂.

The glass frit may include alkali metal oxide, for example one or more selected from Li₂O, Na₂O, K₂O, and Rb₂O, preferably one or more selected from Li₂O, Na₂O and K₂O, more preferably one or both of Li₂O and Na₂O. In some embodiments, it is preferred that the glass frit includes Li₂O.

The glass frit may include 0 wt % or more, 0.1 wt % or more, 0.5 wt % or more or 1 wt % or more alkali metal oxide. The glass frit may include 10 wt % or less, 8 wt % or less, 7 wt % or less, 5 wt % or less, 4 wt % or less alkali metal oxide.

The glass frit may include 0 wt % or more, 0.1 wt % or more, 0.5 wt % or more or 1 wt % or more Li₂O. The glass frit may include 10 wt % or less, 8 wt % or less, 7 wt % or less, 6 wt % or less 5 wt % or less, 4 wt % or less Li₂O. For example, the glass frit may include 0.5 to 6 wt % of Li₂O.

In some embodiments, it may be preferred that the glass frit includes both Li₂O and Na₂O. The glass frit may include 0.1 wt % or more, 0.5 wt % or more, 1 wt % or more, 2 wt % or more or 3 wt % or more in total of Li₂O and Na₂O. The glass frit may include 10 wt % or less, 8 wt % or less, 7 wt % or less, 6 wt % or less 5 wt % or less, 4 wt % or less in total of Li₂O and Na₂O. The glass frit may include at least 0.1 wt % or at least 0.5 wt % of Li₂O and at least 0.1 wt % or at least 0.5 wt % of Na₂O. The glass frit may include 5 wt % or less, 4 wt % or less, 3 wt % or less or 2.5 wt % or less of Li₂O and 5 wt % or less, 4 wt % or less, 3 wt % or less or 2.5 wt % or less of Na₂O.

The glass frit may include ZnO. For example, the glass frit may include 0 wt % or more, 0.1 wt % or more, 0.5 wt % or more, 1 wt % or more or 1.5 wt % or more ZnO. The glass frit may include 15 wt % or less, 10 wt % or less, 7 wt % or less or 5 wt % or less ZnO. For example, the glass frit may include 0.5 to 7 wt % of ZnO.

In some embodiments, it may be preferred that the glass frit is substantially zinc-free. As used herein, the term “substantially zinc-free” is intended to include glass frits which contain no intentionally added zinc. For example, the glass frit may include less than 0.1 wt % ZnO, for example less than 0.05 wt %, less than 0.01 wt % or less than 0.005 wt % ZnO.

The glass frit may include MoO₃. For example, the glass frit may include 0 wt % or more, 0.1 wt % or more, 0.5 wt % or more of MoO₃. The glass frit may include 10 wt % or less, 5 wt % or less, or 3 wt % or less of MoO₃. For example, the glass frit may include 0.1 to 5 wt % of MoO₃.

In some embodiments, it may be preferred that the glass frit is substantially molybdenum-free. As used herein, the term “substantially molybdenum-free” is intended to include glass frits which contain no intentionally added molybdenum. For example, the glass frit may include less than 0.1 wt % MoO₃, for example less than 0.05 wt %, less than 0.01 wt % or less than 0.005 wt % MoO₃.

The glass frit may include Cr₂O₃. For example, the glass frit may include 0 wt % or more, 0.1 wt % or more, 0.5 wt % or more of Cr₂O₃. The glass frit may include 10 wt % or less, 5 wt % or less, or 3 wt % or less of Cr₂O₃. For example, the glass frit may include 0.1 to 5 wt % of Cr₂O₃.

In some embodiments, it may be preferred that the glass frit is substantially chromium-free. As used herein, the term “substantially chromium-free” is intended to include glass frits which contain no intentionally added chromium. For example, the glass frit may include less than 0.1 wt % Cr₂O₃, for example less than 0.05 wt %, less than 0.01 wt % or less than 0.005 wt % Cr₂O₃.

The glass frit may include WO₃. For example, the glass frit may include 0 wt % or more, 0.1 wt % or more, 0.5 wt % or more of WO₃. The glass frit may include 10 wt % or less, 5 wt % or less, or 3 wt % or less of WO₃. For example, the glass frit may include 0.1 to 5 wt % of WO₃.

In some embodiments, it may be preferred that the glass frit is substantially tungsten-free. As used herein, the term “substantially tungsten-free” is intended to include glass frits which contain no intentionally added tungsten. For example, the glass frit may include less than 0.1 wt % WO₃, for example less than 0.05 wt %, less than 0.01 wt % or less than 0.005 wt % WO₃.

The glass frit may include BaO. For example, the glass frit may include 0 wt % or more, 0.1 wt % or more, 0.5 wt % or more of BaO. The glass frit may include 10 wt % or less, 5 wt % or less, or 3 wt % or less of BaO. For example, the glass frit may include 0.1 to 5 wt % of BaO.

The glass frit may include P₂O₅. For example, the glass frit may include 0 wt % or more, 0.1 wt % or more, 0.5 wt % or more or 1 wt % or more P₂O₅. The glass frit may include 10 wt % or less, 7 wt % or less, 5 wt % or less or 3 wt % or less P₂O₅.

The glass frit may include further components, such as further oxide components. Typically, the glass frit will include 20 wt % or less, 10 wt % or less, 7 wt % or less, 5 wt % or less, 3 wt % or less, 2 wt % or less or 1 wt % or less in total of further components. The glass frit may include at least 0.1 wt % of further components. The further components may be one or more selected from the group consisting of GeO₂, CaO, ZrO₂, CuO, Ag₂O and Al₂O₃.

In a preferred embodiment, the glass frit may comprise:
35 to 65 wt % TeO₂;
20 to 50 wt % Bi₂O₃;
0.1 to 5 wt % Li₂O;
0 to 5 wt % Na₂O;
0 to 5 wt % SiO₂;
0.1 to 5 wt % ZnO;
0 to 5 wt % MoO₃;
0 to 5 wt % Cr₂O₃ and
0 to 15 wt % CeO₂.

The glass frit may consist essentially of a composition as described herein, and incidental impurities. In that case, as the skilled person will readily understand that the total weight % of the recited constituents will be 100 wt %, any balance being incidental impurities. Typically, any incidental impurity will be present at 0.1 wt % or less, 0.05 wt % or less, 0.01 wt % or less, 0.05 wt % or less, 0.001 wt % or less or 0.0001 wt % or less.

The glass frit composition may consist essentially of:

35 to 65 wt % TeO₂;
20 to 50 wt % Bi₂O₃;
0.1 to 5 wt % Li₂O;
0 to 5 wt % Na₂O;
0 to 5 wt % SiO₂;
0.1 to 5 wt % ZnO;
0 to 5 wt % MoO₃;
0 to 5 wt % Cr₂O₃;
0 to 15 wt % CeO₂;
0 to 3 wt % WO3;
0 to 5 wt % BaO;
0 to 10 wt % P₂O₅;
0 to 10 wt % of further components, which may optionally be selected from the group consisting of GeO₂, CaO, ZrO₂, CuO, Ag₂O and Al₂O₃; and incidental impurities.

The solids portion of the conductive paste of the present invention may include 0.1 to 15 wt % of glass frit. The solids portion of the conductive paste may include at least 0.5 wt % or at least 1 wt % of glass frit. The solids portion of the conductive paste may include 10 wt % or less, 7 wt % or less or 5 wt % or less of glass frit.

Typically, the glass frit will have a softening point in the range from 200° C. to 400° C. For example, the glass frit may have a softening point in the range from 250° C. to 350° C. The softening point may be determined e.g. using DSC measurement according to the standard ASTM E1356 “Standard Test Method for Assignment of the Glass Transition Temperature by Differential Scanning calorimetry”.

The particle size of the glass frit powder is not particularly limited in the present invention. Typically, the D₅₀ particle size may be at least 0.1 μm, at least 0.5 μm, or at least 1 μm. The D₅₀ particle size may be 15 μm or less, 10 μm or less, 5 μm or less, 4 μm or less, 3 μm or less or 2 μm or less or 1 μm or less. The particle size may be determined using a laser diffraction method (e.g. using a Malvern Mastersizer 2000).

Using X-ray diffraction techniques, the present inventors have found that some of the glass frits they have prepared in fact include a crystalline portion. Accordingly, it will be understood that the glass frits described and defined herein may include a crystalline portion in addition to an amorphous glass phase. In particular, the present inventors have found that some glass frits which include CeO₂ as a component in fact include a portion of crystalline CeO₂, in addition to the amorphous glass phase. This is observed particularly where the glass frit recipe includes a large weight percent of CeO₂, (e.g. 5 wt % or more). Accordingly, it will be understood that the glass frits described herein may include crystalline CeO₂, and that the recited CeO₂ content of the frit relates to the total of CeO₂ in amorphous glass phase and crystalline phase in the frit. Similarly, where another component is present in a crystalline portion, the recited content of that component in the frit relates to the total of that component in amorphous glass phase and crystalline phase in the frit. The glass frit is typically obtained or obtainable by a process as described or defined herein.

Typically, the glass frit is prepared by mixing together the raw materials and melting them to form a molten glass mixture, then quenching to form the frit. The process may further comprise milling the frit to provide the desired particle size.

The skilled person is aware of alternative suitable methods for preparing glass frit. Suitable alternative methods include water quenching, sol-gel processes and spray pyrolysis.

### Conductive Paste

Typically, the conductive paste is a front side conductive paste.

The conductive paste comprises the electrically conductive metal, the inorganic particle mixture and the organic vehicle. The conductive paste may consist of the electrically conductive metal, the inorganic particle mixture and the organic vehicle.

The solids portion of the conductive paste of the present invention may include 80 to 99.9 wt % of electrically conductive metal. For example, the solids portion may include at least 80 wt %, at least 82 wt %, at least 85 wt % or at least 87 wt % at least 90 wt %, at least 93 wt % or at least 95 wt % of electrically conductive metal. The solids portion may include 99.9 wt % or less, 99.5 wt % or less, 99 wt % or less or 98 wt % or less of electrically conductive metal.

The electrically conductive metal may comprise one or more metals selected from silver, copper, nickel and aluminium. Preferably, the electrically conductive metal comprises or consists of silver.

The electrically conductive metal may be provided in the form of metal particles. The form of the metal particles is not particularly limited, but may be in the form of flakes, spherical particles, granules, crystals, powder or other irregular particles, or mixtures thereof.

The particle size of the electrically conductive metal is not particularly limited in the present invention. Typically, the D₅₀ particle size may be at least 0.1 μm, at least 0.5 μm, or at least 1 μm. The D₅₀ particle size may be 15 μm or less, 10 μm or less, 5 μm or less, 4 μm or less, 3 μm or less or 2 μm or less. The particle size may be determined using a laser diffraction method (e.g. using a Malvern Mastersizer 2000).

The surface area of the electrically conductive material is not particularly limited in the present invention. For example, it may be at least 0.1 m²/g, at least 0.2 m²/g, at least 0.3 m²/g, at least 0.4 m²/g or at least 0.5 m²/g. For example, it may be 5 m²/g or less, 3 m²/g or less, 2 m²/g or less, 1 m²/g or less, 0.8 m²/g or less or 0.7 m²/g or less.

Where the conductive material is, or includes, silver, suitably a silver powder may be used. A suitable silver powder is Metalor® 554-2. Alternative suitable silver powders are commercially available from Technic.

The solids portion of the conductive paste of the present invention may include 0.01 to 5 wt % of inorganic particle mixture. For example, the solids portion may include at least 0.05 wt %, at least 0.1 wt %, at least 0.5 wt %, at least 1 wt %, at least 1.5 wt % or at least 2 wt % of inorganic particle mixture. The solids portion may include 4 wt % or less, 3.5 wt % or less or 3 wt % or less inorganic particle mixture.

In some embodiments, the solids portion of the conductive paste of the present invention may include 0.1 to 15 wt % of glass frit. For example, the solids portion may include at least 0.2 wt %, at least 0.5 wt % or at least wt % of glass frit. The solids portion may include 10 wt % or less, 7 wt % or less or 5 wt % or less of glass frit.

### Organic Medium

The solids portion of the conductive paste of the present invention is dispersed in organic medium. The organic medium is preferably a liquid organic medium. The organic medium may constitute, for example, at least 2 wt %, at least 5 wt % or at least 9 wt % of the conductive paste. The organic medium may constitute 20 wt % or less, 15 wt % or less, 13 wt % or less or 10 wt % or less of the conductive paste.

Accordingly, it will be understood that the solids portion may constitute at least 80 wt %, at least 85 wt %, at least 87 wt % or at least 90 wt % of the conductive paste. The solids portion may constitute 98 wt % or less, 95 wt % or less or 91 wt % or less of the conductive paste.

In some embodiments, the conductive paste consists of the solids portion and the organic medium.

The organic medium typically comprises an organic solvent with one or more additives dissolved or dispersed therein. As the skilled person will readily understand, the components of the organic medium are typically chosen to provide suitable consistency and rheology properties to permit the conductive paste to be printed onto a semiconductor substrate, and to render the paste stable during transport and storage.

Examples of suitable solvents for the organic medium include one or more solvents selected from the group consisting of butyl diglycol, butyldiglycol acetate, terpineol, diakylene glycol alkyl ethers (such as diethylene glycol dibutyl ether and tripropyleneglycol monomethylether), ester alcohol (such as Texanol®), 2-(2-methoxypropoxy)-1-propanol and mixtures thereof.

Examples of suitable additives include those dispersants to assist dispersion of the solids portion in the paste, viscosity/rheology modifiers, thixotropy modifiers, wetting agents, thickeners, stabilisers and surfactants.

For example, the organic medium may comprise one or more selected from the group consisting of rosin (kollophonium resin), acrylic resin (e.g. Neocryl®), alkylammonium salt of a polycarboxylic acid polymer (e.g. Dysperbik® 110 or 111), polyamide wax (such as Thixatrol Plus® or Thixatrol Max®), nitrocellulose, ethylcellulose, hydroxypropyl cellulose and lecithin.

Typically, the conductive paste is prepared by mixing together the above-described components of the solids portion and the components of the organic medium, in any order. In a further preferred aspect, the present invention provides a process for preparing a conductive paste according to the first aspect, wherein the process comprises mixing together the above-described components of the solids portion and the components of the organic medium, in any order.

### Method of Preparing a Conductive Paste

In some embodiments, the method of preparing the conductive paste comprises co-milling the substantially crystalline particles of the inorganic particle mixture before they are mixed with the organic medium and the electrically conductive metal.

In some embodiments, the method of preparing the conductive paste comprises milling each component of the inorganic particle mixture separately prior to mixing the organic medium, the electrically conductive material, and the components of the inorganic particle mixture.

### Manufacture of a Light Receiving Surface Electrode and Solar Cell

The skilled person is familiar with suitable methods for the manufacture of a light receiving surface electrode of a solar cell. Similarly, the skilled person is familiar with suitable methods for the manufacture of a solar cell.

The method for the manufacture of a light receiving surface electrode of a solar cell typically comprises applying a conductive paste onto the surface of a semiconductor substrate, and firing the applied conductive paste.

The conductive paste may be applied by any suitable method. For example, the conductive paste may be applied by printing, such as by screen printing or inkjet printing. The conductive paste may be applied on a semiconductor substrate to form a light receiving surface electrode of a solar cell. Alternatively, the conductive paste may be applied on a semiconductor substrate to form a back side surface electrode of a solar cell. The solar cell may be an n-type or a p-type solar cell. The paste may be applied onto an n-type emitter (in a p-type solar cell), or onto a p-type emitter (in an n-type solar cell). Some solar cells are known as back junction cells. In this case, it may be preferred that the conductive paste of the present invention is applied to the back side surface of the semiconductor substrate of the solar cell. Such a back side surface is typically covered with an insulating passivation layer (e.g. SiN layer), similar to the anti-reflective coating applied to the light receiving surface of a solar cell. Alternatively, the conductive paste may be applied to a thin film solar cell or the conductive paste may be applied to a substrate for an electronic device other than a solar cell.

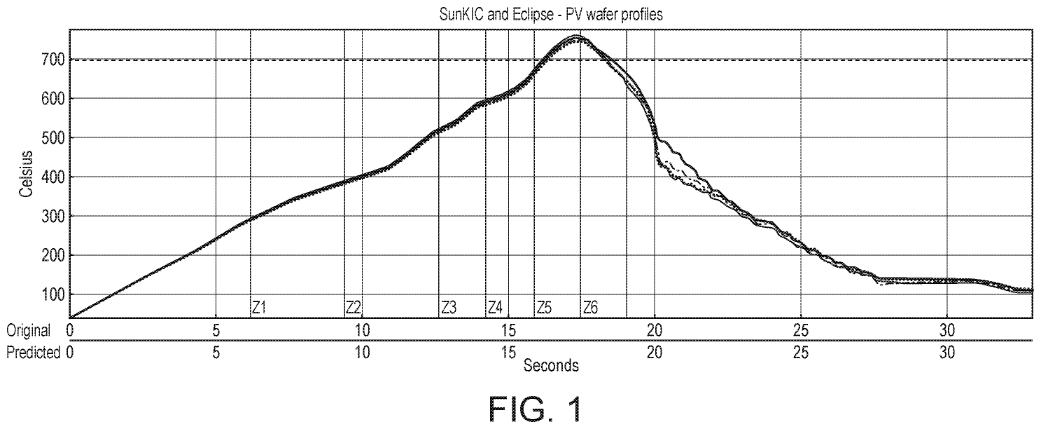

The skilled person is aware of suitable techniques for firing the applied conductive paste. An example firing curve is shown in FIG. 1. A typical firing process lasts approximately 30 seconds, with the surface of the light receiving surface electrode reaching a peak temperature of about 800° C. Typically the furnace temperature will be higher to achieve this surface temperature. The firing may for example last for 1 hour or less, 30 minutes or less, 10 minutes or less or 5 minutes or less. The firing may last at least 10 seconds. For example, the peak surface temperature of the light receiving surface electrode may be 1200° C. or less, 1100° C. or less, 1000° C. or less, 950° C. or less or 900° C. or less. The peak surface temperature of the light receiving surface electrode may be at least 600° C.

The semiconductor substrate of the light receiving surface electrode may be a silicon substrate. For example, it may be a single crystal semiconductor substrate, or a multi crystal semiconductor substrate. Alternative substrates include CdTe. The semiconductor may for example be a p-type semiconductor or an n-type semiconductor.

The semiconductor substrate may comprise an insulating layer on a surface thereof. Typically the conductive paste of the present invention is applied on top of the insulating layer to form the light receiving surface electrode. Typically, the insulating layer will be non-reflective. A suitable insulating layer is SiNₓ (e.g. SiN). Other suitable insulating layers include Si₃N₄, SiO₂, Al₂O₃ and TiO₂.

Methods for the manufacture of a p-type solar cell typically comprise applying a back side conductive paste (e.g. comprising aluminium) to a surface of the semiconductor substrate, and firing the back side conductive paste to form a back side electrode. The back side conductive paste is typically applied to the opposite face of the semiconductor substrate from the light receiving surface electrode.

In the manufacture of p-type solar cells, typically, the back side conductive paste is applied to the back side (non-light receiving side) of the semiconductor substrate and dried on the substrate, after which the front side conductive paste is applied to the front side (light-receiving side) of the semiconductor substrate and dried on the substrate. Alternatively, the front side paste may be applied first, followed by application of the back side paste. The conductive pastes are typically co-fired (i.e. the substrate having both front- and back-side pastes applied thereto is fired), to form a solar cell comprising front- and back-side conductive tracks.

The efficiency of the solar cell may be improved by providing a passivation layer on the back side of the substrate. Suitable materials include SiNx (e.g. SiN), Si₃N₄, SiO₂, Al₂O₃ and TiO₂. Typically, regions of the passivation layer are locally removed (e.g. by laser ablation) to permit contact between the semiconductor substrate and the back side conductive track. Alternatively, where pastes of the present invention are applied to the back side, the paste may act to etch the passivation layer to enable electrical contact to form between the semiconductor substrate and the conductive track.

Where ranges are specified herein it is intended that each endpoint of the range is independent. Accordingly, it is expressly contemplated that each recited upper endpoint of a range is independently combinable with each recited lower endpoint, and vice versa.

### EXAMPLES

### Inorganic Blend Preparation

Inorganic blends were prepared using commercially available raw materials. The compositions of the inorganic blends are given in Tables 1 and 2 below.

TABLE 1
Inorganic blend compositions
(Compositions in weight % on an oxide basis)

| | X | |
|---|---|---|
| Composition | (Comparative) | A |
| TeO₂/wt % | 54.6 | 54.8 |
| Li₂CO₃/wt % | 6.9 | 6.5 |
| Bi₂O₃/wt % | 27.3 | 27.4 |
| CeO₂/wt % | 3.3 | 3.4 |
| Na₂CO₃/wt % | 3.8 | 3.8 |
| WO₃/wt % | 4.0 | 0 |
| Li_{0.6}WO₃/wt % | 0 | 4.1 |

TABLE 2
Inorganic blend compositions
(Compositions in weight % on an oxide basis)

| Composition | Y (Comparative) | Z (Comparative) | B | C | D |
|---|---|---|---|---|---|
| TeO₂/wt % | 53.6 | 56.0 | 40.5 | 35.2 | 56.5 |
| Li₂CO₃/wt % | 6.8 | 7.1 | 0 | 0 | 5.8 |
| Bi₂O₃/wt % | 26.9 | 28.0 | 28.0 | 28.5 | 28.3 |
| CeO₂/wt % | 6.6 | 3.4 | 6.8 | 6.9 | 3.4 |
| Na₂CO₃/wt % | 3.7 | 3.9 | 3.9 | 0.1 | 3.9 |
| ZnO/wt % | 1.3 | 0 | 1.4 | 1.4 | 0 |
| BaCO₃/wt % | 1.1 | 0 | 1.1 | 1.2 | 0 |
| MnO/wt % | 0 | 1.6 | 0 | 0 | 0 |
| Li₂TeO₃/wt % | 0 | 0 | 18.3 | 0 | 0 |
| Li_{1.45}Na_{0.55}TeO₃/wt % | 0 | 0 | 0 | 26.8 | 0 |
| Li₂MnO₃/wt % | 0 | 0 | 0 | 0 | 2.1 |
| Milling method used | Planetary ball milling | | Planetary ball milling | Planetary ball milling | |
| | (50% powder mixture | | (50% powder mixture | (50% powder mixture | |
| | and 50% glycol- | | and 50% glycol- | and 50% glycol- | |
| | based solvent) | | based solvent) | based solvent) | |
| D₁₀/μm | 0.26 | | 0.21 | 0.24 | |
| D₅₀/μm | 0.65 | | 0.56 | 0.66 | |
| D₉₀/μm | 1.28 | | 1.76 | 2.01 | |

Inorganic blends A, B, C, D, X, Y and Z were prepared by mixing the oxides and carbonates using a laboratory mixer to produce a mixed material, followed by wet milling of the mixed material in glycol-type solvent (e.g. butyldiglycol) to produce a co-milled material. Table 2 further shows the milling conditions and particle size distributions of blends Y, B and C. The resultant blended powders were then dried in a tray drier and sieved.

The Li_{0.6}WO₃ crystalline compound was made by mixing Li₂WO₄ (7.986 g), WO₃ (14.10 g) and W (1.87 g), all of which are commercially available products. These components were ground together by hand then heated at 60° C. for 60 mins followed by a further heating step at 750° C. for 1000 mins under an Ar atmosphere.

The Li₂TeO₃ crystalline compound was prepared by blending lithium carbonate and tellurium oxide, melting at 900° C. for 15 minutes and dry quenching.

The Li_{1.45}Na_{0.55}TeO₃ crystalline compound was prepared by blending lithium carbonate, sodium carbonate and tellurium oxide, melting at 900° C. for 15 minutes and dry quenching.

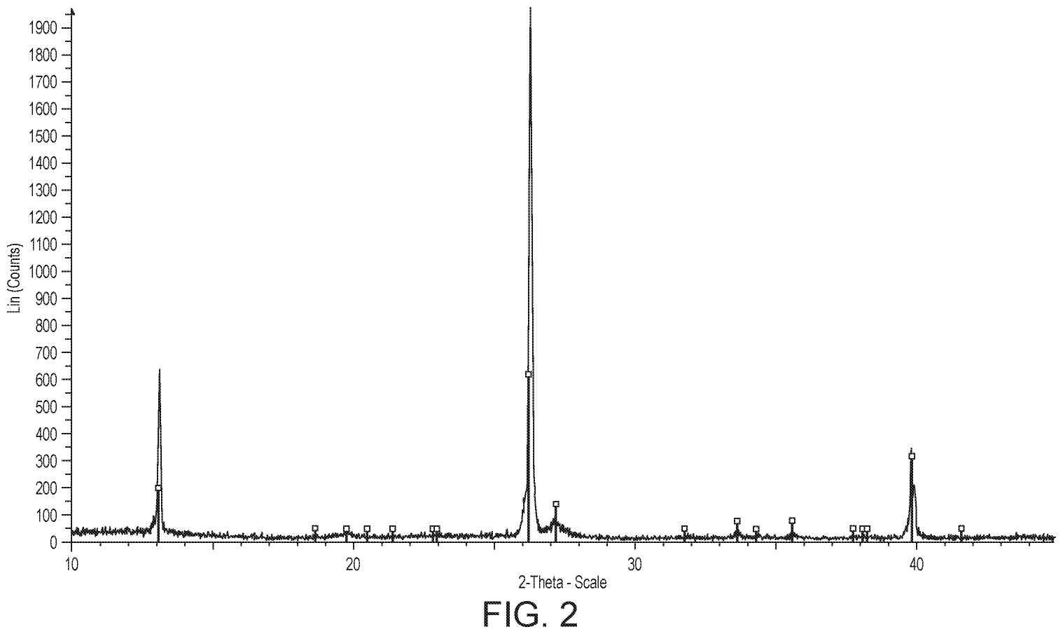

FIG. 2 is an X-ray diffractogram taken for Li₂TeO₃. It shows that a single mixed-oxide crystalline phase is present.

Other components are commercially available.

The metal atomic compositions of X and A are the same. The difference between the blends is that, in composition A, some of the lithium (which was provided by Li₂CO₃ in composition X) and all of the tungsten (which was provided by WO₃ in composition X) is instead provided by Li_{0.6}WO₃. In other words, the relative amounts of metals in the two compositions is the same but the source of the metals is different in composition X all metal sources are crystalline compounds which contain only one metal, whereas in composition A one metal source is a ternary oxide containing two different metals.

The same is true of compositions Y, B and C. All three compositions have the same atomic compositions with regard to metal content. The difference is the partial replacement of TeO₂ and Na₂CO₃ and total replacement of Li₂CO₃ by Li₂TeO₃ (composition B) or Li_{1.45}Na_{0.55}TeO₃ (composition C).

The same is true of compositions Z and D. Both compositions have the same atomic compositions with regard to metal content. The difference is the partial replacement of Li₂CO₃ and full replacement of MnO₂ by Li₂MnO₃.

### Solar Cell Formation

Multicrystalline wafers with sheet resistance of 90 Ohm/sq, 6 inches size, were screen printed on their back side with commercially available aluminium paste, dried in an IR Mass belt dryer and randomized in groups. Each of these groups was screen printed with a front side silver paste which was one of the conductive pastes described herein and set out in more detail above.

The screens used for the front side pastes had finger opening 50 μm. After printing the front side, the cells were dried in the IR Mass belt dryer and fired in a Despatch belt furnace. The Despatch furnace had six firing zones with upper and lower heaters. The first three zones are programmed around 500° C. for burning of the binder from the paste, the fourth and fifth zone are at a higher temperature, with a maximum temperature of 945° C. in the final zone (furnace temperature). The furnace belt speed for this experiment was 610 cm/min. The recorded temperature was determined by measuring the temperature at the surface of the solar cell during the firing process using a thermocouple. The temperature at the surface of the solar cell did not exceed 800° C. This is typical of the firing temperature employed for pastes comprising a glass which typically has a softening point of about 600° C. It is surprising that such good flow behaviour and contact formation are observed for the crystalline inorganic particle mixture of the present invention.

After cooling the fired solar cells were tested in an I-V curve tracer from Halm, model cetisPV-CTL1. The results are provided by the I-V curve tracer, either by direct measurement or calculation using its internal software.

(To minimise the influence of the contact area the cells were prepared using the same screen for printing, and the same viscosity paste in each individual test set. This ensures that the line widths of the compared pastes were substantially identical and had no influence on the measuring).

### Solar Cell Performance

Fill factor indicates the performance of the solar cell relative to a theoretical ideal (0 resistance) system. The fill factor correlates with the contact resistance—the lower the contact resistance the higher the fill factor will be. But if the inorganic additive of the conductive paste is too aggressive it could damage the p-n junction of the semiconductor. In this case the contact resistance would be low but due to the damage of the p-n junction (recombination effects and lower shunt resistance) a lower fill factor would occur. A high fill factor therefore indicates that there is a low contact resistance between silicon wafer and the conductive track, and that firing of the paste on the semiconductor has not negatively affected the p-n junction of the semiconductor (i.e. the shunt resistance is high).

The quality of the p-n junction can be determined by measuring the pseudo fill factor (SunsVocFF). This is the fill factor independent of losses due to resistance in the cell. Accordingly, the lower the contact resistance and the higher the SunsVocFF, the higher the resulting fill factor will be. The SunsVocFF was measured using a Suns-Voc measurement tool from Sinton Instruments. SunsVocFF is measured under open circuit conditions, and is independent of series resistance effects.

Eta represents the efficiency of the solar cell, comparing solar energy in to electrical energy out. Small changes in efficiency can be very valuable in commercial solar cells.

### Example 1

A conductive silver paste (Example 1) was prepared using 87.5 wt % of a commercial silver powder, 2.5 wt % of Composition A detailed above, with the balance being standard organic medium. A comparison paste (Comparative Example 1) was made which contained 87.5 wt % silver powder, 2.5 wt % Comparative Composition X and the balance organic medium. The pastes were prepared by Turbula mixing the inorganic blend composition for 30 mins before 10 g of the mixed powder was speedy-mixed twice with 10 g of ZrO₂ 2 mm balls, at 3000 rpm for 30 s each time, producing a homogeneous paste.

The printed contacts on the Si₃N₄ coated silicon wafers were then fired at 640° C. using a Rapid Thermal Processing furnace. The firing process was very short (30-60 seconds), during which time the contact between the printed silver paste and the p-n junction with the silicon wafer is created.

Specific contact resistance measurements (Ω·mm⁻²) of the silver contacts on a Si₃N₄/Si wafer were carried out using the TLM method for measuring specific contact resistance. The results are shown in Table 3 below.

TABLE 3
Specific Contact Resistance measurements
Specific contact resistance/Ω · mm²

| Example 1 - | Comparative Example 1 - |
|---|---|
| Composition A | Composition X |
| 9 | 13 |

The results show that specific contact resistance is improved (i.e. lower) for the inventive composition in which some of the metals in the inorganic particle mixture are provided by a crystalline mixed oxide source rather than crystalline single metal oxide sources.

### Example 2

A conductive silver paste (Example 2A) was prepared using 87.75 wt % of a commercial silver powder, 2.25 wt % of Composition B detailed above, with the balance being standard organic medium. A conductive silver paste (Example 2B) was prepared using 87.75 wt % of a commercial silver powder, 2.25 wt % of Composition C detailed above, with the balance being standard organic medium.

A comparison paste (Comparative Example 2) was made which contained 87.75 wt % silver powder, 2.25 wt % Comparative Composition Y and the balance organic medium. The pastes were prepared in the same way as Example 1.

The pastes were printed in multicrystalline wafers, high ohmic emitters, dried and fired using the method outlined above.

Series resistance measurements (Ω·cm²) of silver contacts on a Si₃N₄/Si wafer were carried out. The results are shown in Table 4 below.

TABLE 4
Series Resistance measurements
Series resistance/Ω · cm²

| Example 2A - | Example 2B - | Comparative Example 2 - |
|---|---|---|
| Composition B | Composition C | Composition Y |
| 0.00267 | 0.00275 | 0.00295 |

The results show that series resistance is improved (i.e. lower) for the inventive compositions in which some of the metals in the inorganic particle mixture are provided by a crystalline mixed oxide source rather than crystalline single metal oxide sources.

### Example 3

A conductive silver paste (Example 3A) was prepared using 87.75 wt % of a commercial silver powder, 2.25 wt % of Composition D detailed above, with the balance being standard organic medium.

A comparison paste (Comparative Example 3) was made which contained 87.75 wt % silver powder, 2.25 wt % Comparative Composition Z and the balance organic medium. The pastes were prepared in the same way as Example 1.

Printing of the pastes using TLM screen design was carried out and the printed pastes were fired in an RTP furnace at 640° C. Seven separate samples were prepared. Specific contact resistance was determined for each sample and the average determined; results are given in Table 5 below.

TABLE 5
Specific Contact Resistance measurements
Specific contact resistance/Ω · mm²

| Example 3 - | Comparative Example 3 - |
|---|---|
| Composition D | Composition Z |
| 1.128 ± 0.110 | 3.367 ± 0.204 |

Printing with the Suns V_{OC} screen design was also carried out for the two compositions followed by firing in an RTP furnace at 640° C. Ten separate samples were prepared, SunsVocFF was determined for each and the average was calculated; results are provided in Table 6 below.

TABLE 6
SunsVocFF measurements

pFF

| | Example 3 - | Comparative Example 3 - |
|---|---|---|
| | Composition D | Composition Z |
| SunsVocFF | 0.7379 ± 0.0088 | 0.6692 ± 0.0139 |
| Max SunsVocFF | 0.735 | 0.735 |

The results show that the substitution of Li₂MnO₃ for MnO₂ has no detrimental impact on the specific contact resistance or the SunsV_{OC} measurement. It appears that the presence of Li₂MnO₃ in the paste instead of MnO₂ had a positive impact on both the specific contact resistance and the SunsV_{OC} measurement.

1. A conductive paste for forming a conductive track or coating on a substrate, the paste comprising a solids portion dispersed in an organic medium,
the solids portion comprising electrically conductive material and an inorganic particle mixture;
wherein the inorganic particle mixture comprises substantially crystalline particles of a compound having the general formula AₓB_{y}O_{z} and substantially crystalline particles of a compound of element D selected from binary oxides, carbonates, hydrogen carbonates, nitrates, acetates, oxalates, formates and organometallic compounds;
wherein:
A is a metal or mixture of two different metals;
B is a metal or metalloid different to A;
D is a metal or metalloid;
0<x≤2;
y is an integer; and
z is an integer;
wherein the solids portion has a lead content of less than 0.01 wt %, and,
wherein the inorganic particle mixture comprises a compound of tellurium and a compound of lithium.

2. The conductive paste according to claim 1, wherein the compound of tellurium comprises one or both of elements B and D.

3. The conductive paste according to claim 1, wherein the compound of lithium comprises one or both of elements A and D.

4. (canceled)

5. The conductive paste according to claim 1, wherein the compound of element D is a compound having the general formula DₘOₙ;
wherein:
D is a metal or metalloid;
m is an integer; and
n is an integer.

6. The conductive paste according to claim 1, wherein wherein D is Te, Bi, or Ce.

7. (canceled)

8. The conductive paste according to claim 1, wherein A is an alkali metal or mixture of two or more alkali metals.

9. (canceled)

10. The conductive paste according to claim 1, wherein the glass content of the solids portion is less than 1 wt %, preferably less than 0.5 wt %, preferably less than 0.25 wt %, more preferably less than 0.05 wt %, most preferably less than 0.01 wt %.

11. (canceled)

12. The conductive paste according to claim 1, wherein A is selected from Li, Na or a mixture of Li and Na.

13. The conductive paste according to claim 1, wherein B is selected from transition metals, post-transition metals, lanthanides and metalloids.

14. The conductive paste according to claim 13, wherein B is selected from transition metals and metalloids.

15. The conductive paste according to claim 14, wherein B is selected from Ti, W and Te.

16.-22. (canceled)

23. The conductive paste according to claim 1, wherein the inorganic particle mixture further comprises auxiliary inorganic materials consisting of metal or metalloid compounds selected from oxides, carbonates, nitrates, hydrogen carbonates, oxalates, acetates and/or formates.

24.-27. (canceled)

28. The conductive paste according to claim 1 wherein the electrically conductive material comprises or consists of silver.

29.-31. (canceled)

32. The conductive paste according to claim 1, wherein the particles of the inorganic particle mixture have a particle size distribution in which one or more of the following conditions applies:
(a) D10≤0.41 μm;
(b) D50≤1.6 μm;
(c) D90≤4.1 μm;
(d) (D50−D10)≤1.15 μm;
(e) (D90−D50)≤2.5 μm;
(f) (D90−D10)≤3.7 μm; or
(g) (D50/D10)≤3.85.

33.-35. (canceled)

36. A method for the manufacture of a surface electrode of a solar cell, the method comprising applying a conductive paste as defined in claim 1 to a semiconductor substrate, and firing the applied conductive paste.

37. An electrode for a solar cell, the electrode comprising a conductive track on a semiconductor substrate, wherein the conductive track is obtained or obtainable by firing a paste as defined in claim 1 on the semiconductor substrate.

38.-40. (canceled)
